(19) United States
(12) Patent Application Publication
(10) Pub. No.: US 2014/0084947 A1
(43) Pub. Date: Mar. 27, 2014

(54) System and Method for Measuring Product Quantity in a Container

(71) Applicant: MEADWESTVACO CORPORATION, Richmond, VA (US)

(72) Inventors: James Fortuna, Richmond, VA (US); Steven Burton, Richmond, VA (US); Christopher Jameson, Henrico, VA (US)

(73) Assignee: MeadWestvaco Corporation, Richamond, VA (US)

(21) Appl. No.: 13/628,150

(22) Filed: Sep. 27, 2012

(51) Int. Cl. G01R 27/26

(52) U.S. Cl. 324/663

(57) ABSTRACT

A system for measuring product quantity including a container that defines an internal volume, a plurality of products positioned in the internal volume, a first conductor positioned proximate the container, a second conductor positioned proximate the container, the second conductor being spaced a distance from the first conductor, and a capacitance meter electrically coupled to the first and second conductors.

### FIELD

This application relates to product dispensing and, more particularly, to systems and methods for determining the quantity of products in a container, such as a container associated with a product dispensing system.

### BACKGROUND

Products are typically shipped to retailers in bulk by enclosing multiple individual product units in a container, such as a carton or box. For example, canned foods may be shipped to a retailer in a box containing twelve individual cans. Then, it is typically the retailer's obligation to remove the individual product units from the container and present them to consumers on a display (e.g., a shelf).

Product dispensing systems have been developed in an effort to improve operating efficiency over the traditional package-ship-unpack-display model. Product dispensing systems are described in greater detail in U.S. Pat. No. 7,922,437 to Loftin et al. The Loftin product dispensing system includes a dispenser having a frame and an opening tool. The dispenser may be positioned on a retailer's shelf and loaded with product simply by placing a container comprising multiple units of product onto the frame of the dispenser. As the container is being placed onto the frame, the opening tool of the dispenser automatically opens the container such that products move under the force of gravity from the container down to a product display area of the frame.

Many retailers periodically conduct an audit, which requires ascertaining the retailer's inventory at a given time. Taking inventory typically involves counting the total number of each product (e.g., each SKU) the retailer has on hand. When products are presented in the traditional way, taking inventory may require counting each product sitting on the display. When product dispensing systems are used, taking inventory may require the additional step of removing the container from the dispenser and examining the number of products within the container. Therefore, taking inventory may a labor-intensive and costly process.

Accordingly, those skilled in the art continue with research and development efforts in the field of product dispensing.

### SUMMARY

In one embodiment, the disclosed system for measuring product quantity may include a container that defines an internal volume, a plurality of products positioned in the internal volume, a first conductor positioned proximate the container, a second conductor positioned proximate the container, wherein the container, the products, the first conductor and the second conductor form an assembly, and a meter electrically coupled to the first and second conductors to measure an electrical quantity of the assembly.

In another embodiment, the disclosed system for measuring product quantity may include a container that defines an internal volume, a plurality of products positioned in the internal volume, a first conductor positioned proximate the container, a second conductor positioned proximate the container, the second conductor being spaced a distance from the first conductor, and a capacitance meter electrically coupled to the first and second conductors.

In another embodiment, the disclosed method for determining a number of products in a container may include the steps of (1) positioning the container between a first conductor and a second conductor to form a capacitor assembly, (2) measuring a capacitance of the capacitor assembly (e.g., with a capacitance meter), and (3) correlating the measured capacitance to the number of products in the container.

Other embodiments of the disclosed system and method for measuring product quantity in a container will become apparent from the following detailed description, the accompanying drawings and the appended claims.

### BRIEF DESCRIPTION OF THE DRAWINGS

FIG. 1 is a schematic front elevational view of one embodiment of the disclosed system for measuring product quantity;

FIG. 2 is a side and front perspective view of the system of FIG. 1;

FIG. 3 is a front and side perspective view of the container of the system of FIG. 2;

FIG. 4 is a graphical representation of capacitance versus number of products (cans) measured in connection with one experimentation with the system of FIG. 2;

FIG. 5 is a graphical representation of capacitance versus number of products (cans) measured in connection with another experimentation with the disclosed system;

FIG. 6 is a schematic front elevational view of another embodiment of the disclosed system for measuring product quantity;

FIG. 7 is a side and front perspective view of a product dispensing system incorporating the disclosed system for measuring product quantity;

FIG. 8 is a bottom and side perspective view of the container of the product dispensing system of FIG. 7;

FIG. 9 is a cross-sectional view of a side wall of the container of FIG. 8;

FIG. 10 is a side elevational view, in section, of the dispenser of the product dispensing system of FIG. 7; and

FIG. 11 is a hand-held device incorporating the disclosed system for measuring product quantity.

### DETAILED DESCRIPTION

It has now been discovered that the number of products housed in a container, such as a container mounted on a dispenser, may be accurately and consistently measured with a capacitance meter. Without being limited to any particular theory, the container may be considered the dielectric (insulator) between two conductors of a capacitor assembly. As products are removed from the container, the effective dielectric properties of the container may be altered, thereby altering (e.g., decreasing) the capacitance of the capacitor assembly. Therefore, the measured capacitance may be correlated to the number of products housed in the container.

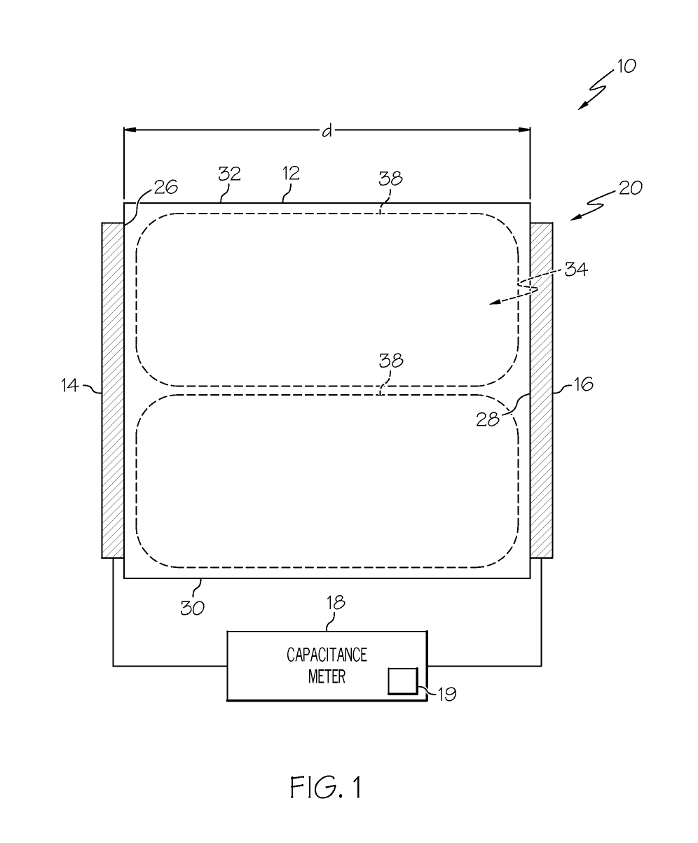

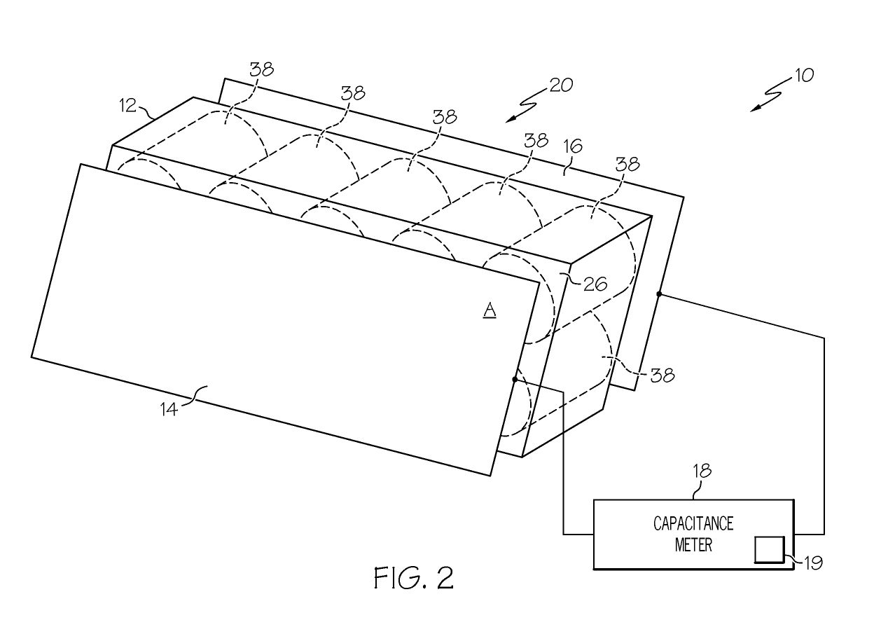

Referring to FIGS. 1 and 2, one embodiment of the disclosed system for measuring product quantity, generally designated 10, may include a container 12, a first conductor 14, a second conductor 16 and a capacitance meter 18. The first and second conductors 14, 16 may be positioned proximate (i.e., at or near) the container 12, thereby effectively forming a capacitor assembly 20. The capacitance meter 18 may be electrically coupled to the first and second conductors 14, 16 to measure the capacitance of the capacitor assembly 20, thereby providing an indication of the number of products 38 (if any) housed in the container 12.

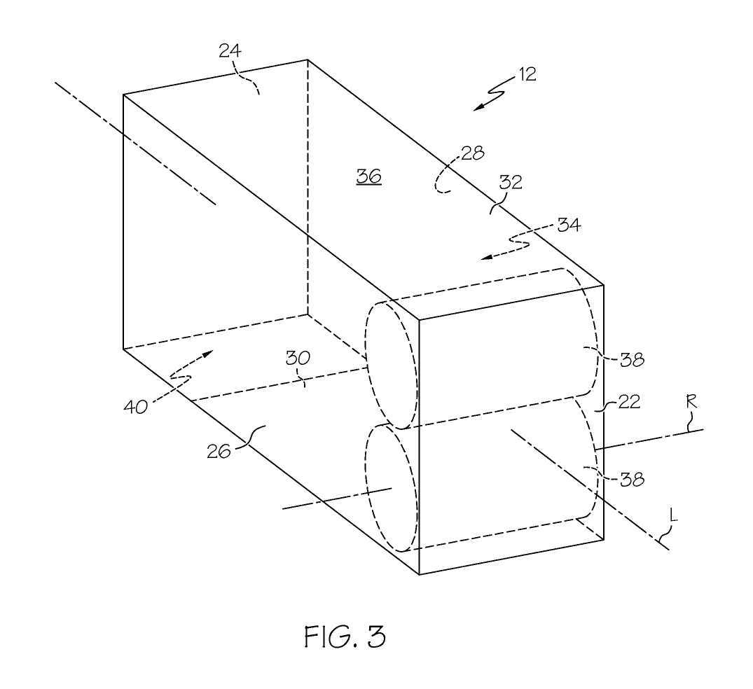

Referring to FIG. 3, the container 12 may be a generally rectilinear container having a longitudinal axis L. The container 12 may be elongated along the longitudinal axis L, and may include six walls 22, 24, 26, 28, 30, 32 that define an internal volume 34. Opposed walls 22 and 24 may define the front and rear walls, respectively, of the container 12. Opposed walls 26 and 28 may define the first (e.g., left) and second (e.g., right) side walls, respectively, of the container 12. Opposed walls 30 and 32 may define the base and upper walls, respectively, of the container 12.

The container 12 may be assembled on a container machine or the like using a container blank that has been pre-cut from a sheet of stock material. As one example, the stock material may be a paperboard-based material, such as C1S paperboard, which may have a coating (e.g., clay) on a first major surface thereof (e.g., the outer surface 36). Optionally, the outer surface 36 of the container 12 may be marked with various indicia, such as advertising text and/or graphics. As another example, the stock material may be C2S paperboard, which may have a coating (e.g., clay) on both major surfaces thereof. Other materials, such as corrugated board, polymeric materials and the like may be used to construct the container 12 without departing from the scope of the present disclosure.

Various products 38 may be housed in the internal volume 34 of the container 12. Non-limiting examples of suitable products 38 include cans (e.g., canned soup or pet food), jars (e.g., jarred sauce) or bottles (e.g., bottled soft drinks). The products 38 may be capable of rolling about a rolling axis R.

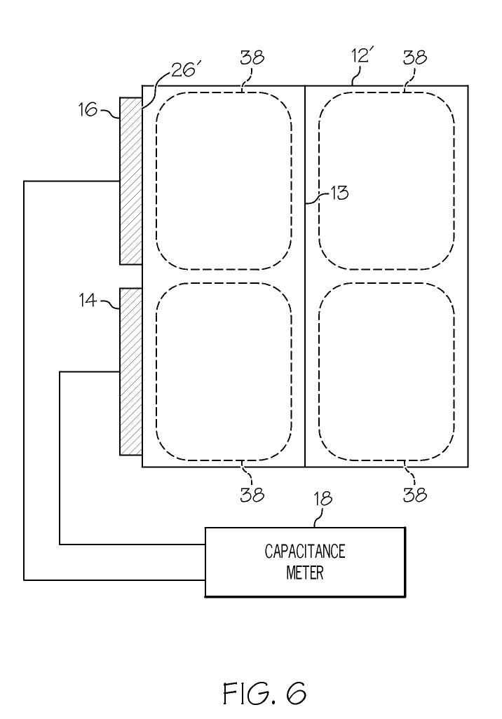

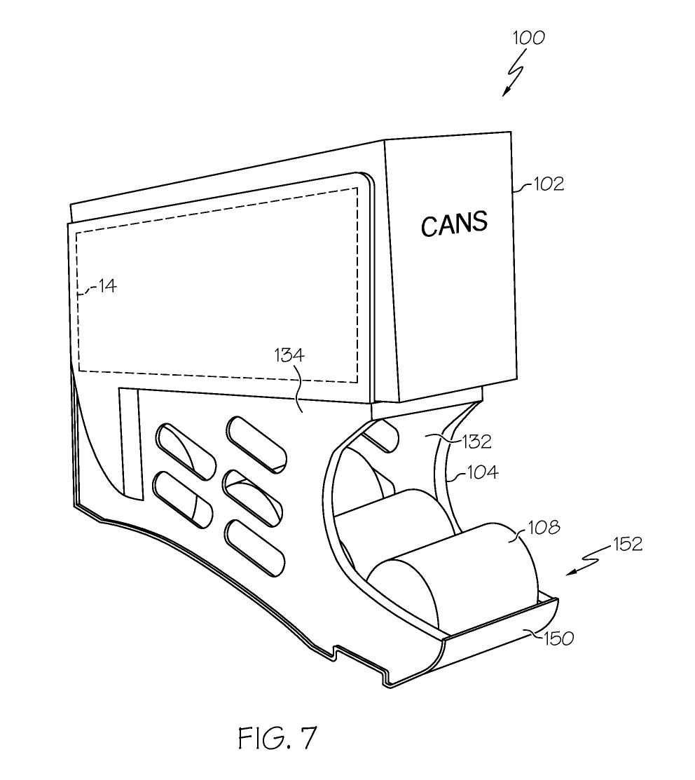

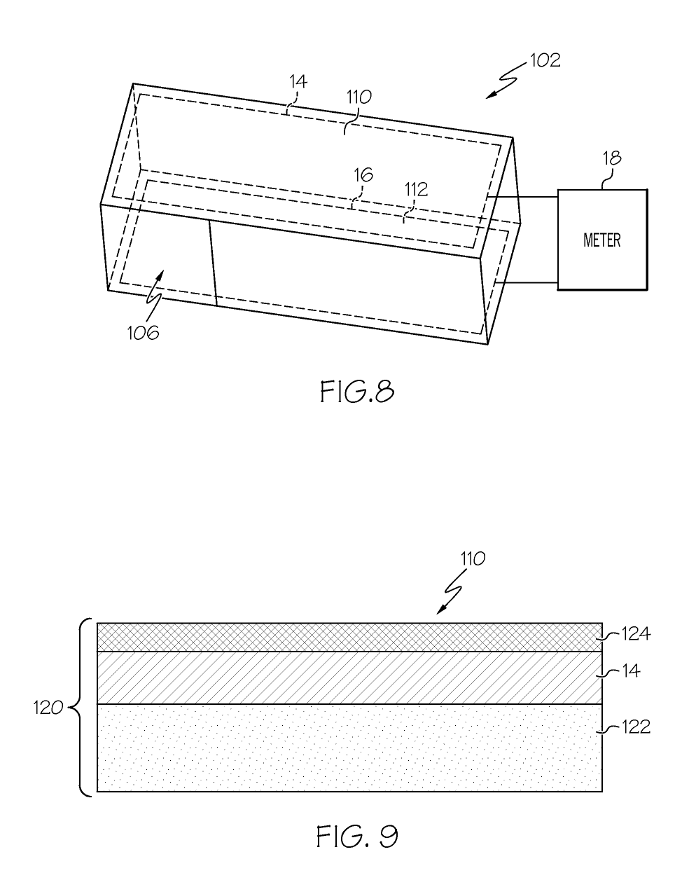

The products 38 may be arranged in various ways within the container 12. As one example, the products 38 may be arranged in two stacked longitudinal rows, with only one row of products 38 between the side walls 26, 28 of the container 12, as shown in FIGS. 1-3. As another example, a first stacked longitudinal row of products 38 may be laterally adjacent to a second stacked longitudinal row or products, as shown in FIG. 6. A divider 13 may optionally separate the laterally adjacent rows within the container 12′.

Still referring to FIG. 3, the container 12 may define a container opening 40 that may provide access to the products 38 housed in the internal volume 34 of the container 12. The container opening 40 may be sized and shaped to allow products 38 to pass therethrough. For example, the container opening 40 may be formed in the base wall 30 proximate the rear wall 24, such that the container 12 may be used in a product dispensing system having a dispenser, as described in greater detail below.

Optionally, the container opening 40 may be initially covered by a tear-away access panel, a peelable label or the like. Therefore, the container opening 40 may be manually formed prior to dispensing (or otherwise removing) products 38 from the container 12. Alternatively, the container opening 40 may be automatically formed in the container 12 upon loading the container 12 onto a dispenser (discussed below).

Referring back to FIGS. 1 and 2, the capacitor assembly 20 may be assembled by positioning the first conductor 14 proximate the left side wall 26 of the container 12 and the second conductor 16 proximate the right side wall 28 of the container 12 such that the first conductor 14 is generally parallel with, and opposed from, the second conductor 16. Therefore, the first conductor 14 may be spaced a distance d (FIG. 1) from the second conductor 16, and the distance d may be dictated by the lateral width of the container 12.

The first and second conductors 14, 16 may be formed from or may include an electrically conductive material. Therefore, various materials may be used to form the first and second conductors 14, 16. In one implementation, the first and second conductors 14, 16 may be formed from (or may include) a metal or metal alloy. Non-limiting examples of suitable metals/alloys include steel, aluminum and copper. In another implementation, the first and second conductors 14, 16 may be formed from (or may include) a metallized polymeric material. Non-limiting examples of suitable metallized polymeric materials include polymeric films, such as polyethylene terephthalate, polyethylene, oriented polypropylene and/or Nylon, coated (or impregnated) with a conductive material, such as an aluminum layer deposited by physical vapor deposition. In yet another implementation, the first and second conductors 14, 16 may be formed from (or may include) an electrically conductive carbon material, such as a nanostructured carbon material. Various other electrically conductive materials are also contemplated.

The first and second conductors 14, 16 may be formed as substantially flat (or flattenable) structures having major surfaces having a surface area A (FIG. 2). In one variation, the first and second conductors 14, 16 may be constructed as substantially rigid structures, such as plates or panels. In another variation, the first and second conductors 14, 16 may be constructed as flexible structures, such as films or foils. In yet another variation, the first and second conductors 14, 16 may be coatings, such as coatings applied directly to the side walls 26, 28 of the container 12.

Those skilled in the art will appreciate that conductors 14, 16 that are not substantially flat plates, films or coatings may also be used. For example, the conductors 14, 16 may be wires, such as two or more parallel wires or a single thin straight wire, discs, contoured plates/films, or the like without departing from the scope of the present disclosure.

The surface areas A of the first and second conductors 14, 16 may closely correspond to the surface areas of the left and right side walls 26, 28, respectively, of the container 12. Therefore, the container 12 may be positioned substantially (if not entirely) between the first and second conductors 14, 16.

In one construction, the surface area A of the first conductor 14 may be at least 50 percent of the surface area of the left side wall 26 of the container 12 and the surface area A of the second conductor 16 may be at least 50 percent of the surface area of the right side wall 28. In another construction, the surface area A of the first conductor 14 may be at least 70 percent of the surface area of the left side wall 26 of the container 12 and the surface area A of the second conductor 16 may be at least 70 percent of the surface area of the right side wall 28. In another construction, the surface area A of the first conductor 14 may be at least 80 percent of the surface area of the left side wall 26 of the container 12 and the surface area A of the second conductor 16 may be at least 80 percent of the surface area of the right side wall 28. In another construction, the surface area A of the first conductor 14 may be at least 90 percent of the surface area of the left side wall 26 of the container 12 and the surface area A of the second conductor 16 may be at least 90 percent of the surface area of the right side wall 28. In another construction, the surface area A of the first conductor 14 may be at least 95 percent of the surface area of the left side wall 26 of the container 12 and the surface area A of the second conductor 16 may be at least 95 percent of the surface area of the right side wall 28. In yet another construction, the surface area A of the first conductor 14 may be at least 100 percent of the surface area of the left side wall 26 of the container 12 and the surface area A of the second conductor 16 may be at least 100 percent of the surface area of the right side wall 28.

With the container 12 positioned between parallel and opposed conductors 14, 16, the capacitor assembly 20 may be configured as a parallel plate capacitor. The capacitance C of a parallel plate capacitor is a function of the permittivity ∈ of the insulator (the container 12 and products 38), the surface area of the conductors 14, 16 A, and the distance d between the conductors 14, 16, as follows:

$$C = ɛ \frac{A}{d} \qquad Eq . 1$$

Thus, as products 38 are removed from the container 12, the permittivity ∈ decreases, resulting in a measurable decrease in the capacitance of the capacitor assembly 20.

The capacitance meter 18 may be electrically coupled to the first and second conductors 14, 16, and may measure the capacitance of the capacitor assembly 20. Any device capable of measuring (either directly or indirectly) the capacitance of the capacitor assembly 20 may be used. For example, the capacitance meter 18 may be a handheld capacitance meter.

The capacitance meter 18 may employ any available technique to measure the capacitance of the capacitor assembly 20. For example, the capacitance meter 18 may apply a known current (e.g., an alternating current) to the conductors 14, 16 of the capacitor assembly 20, and may monitor the change in voltage across the conductors 14, 16 to determine the capacitance. The measured capacitance may be output as a capacitance value or the capacitance value may be converted to a number that is indicative of the number of products 38 within the container 12 (see discussion below regarding correlating capacitance to product quantity). The output of the capacitance meter 18 (e.g., capacitance value and/or product quantity) may be displayed on a display screen 19.

Optionally, the meter 18 may be configured to measure electrical quantities other than (or in addition to) capacitance to determine the number of products 38 within the container 12. Examples of other electrical quantities that may be measured by the meter 18 include, but are not limited to, resistance and inductance.

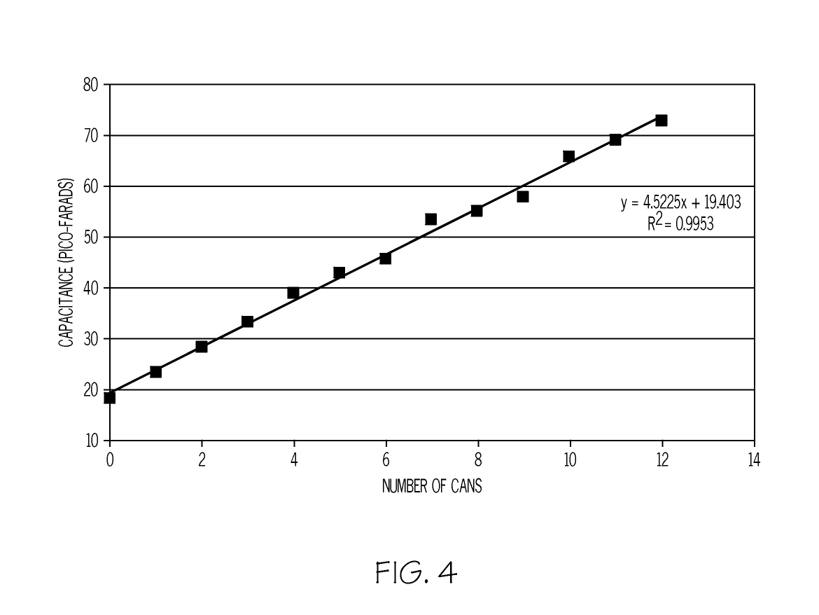

As a first experiment, a system for measuring product quantity was assembled using a paperboard container housing twelve 300×407 (16 ounce) cans of green beans. The container was configured generally as shown in FIG. 3, with six cans initially stacked on top of six cans. Aluminum foil was laminated onto both side walls of the carton to act as the conductors, and a hand-held capacitance meter was electrically coupled to the conductors. A capacitance measurement was taken with all twelve cans in the container. Then, cans were removed one by one, with a capacitance measurement taken after each removal. The results are shown in FIG. 4, with the measured capacitance plotted versus the number of cans in the container.

As can been seen in FIG. 4, there is a generally linear relationship between the measured capacitance and the number of products in the container. As such, the measured capacitance may be correlated to the number of cans in the container. For the example of FIG. 4, the correlation may be expressed as follows:

$$X = \frac{Y - 19.403}{4.5225} \qquad Eq . 2$$

where Y is the measured capacitance and X is the number of cans in the container.

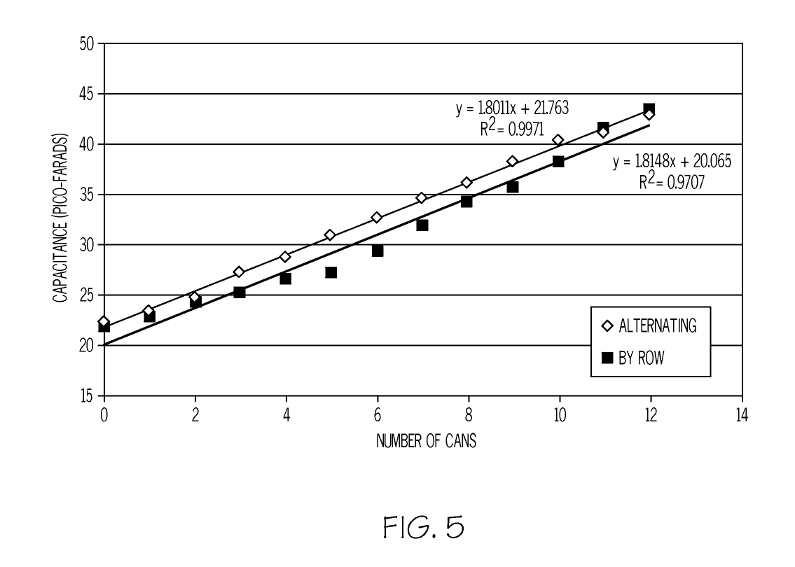

As a second experiment, a system for measuring product quantity was assembled using a paperboard container housing twelve 5.5 ounce cans of wet cat food. The container was configured generally as shown in FIG. 5, with three cans stacked on top of three cans in a first row and three cans stacked on top of three cans in a second, laterally adjacent row. Aluminum foil was laminated onto both side walls of the container to act as the conductors, and a hand-held capacitance meter was coupled to the conductors. A capacitance measurement was taken with all twelve cans in the container. Then, cans were removed one by one, with a capacitance measurement taken after each removal. In one approach, the cans were removed by alternating between laterally adjacent rows. In another approach, the cans were first removed from the first row before then removing cans from the laterally adjacent row. The results (for both approaches) are shown in FIG. 5.

Thus, the number of products 38 within a container 12 may be determined by measuring the capacitance and then determining the quantity of products 38 based on a known correlation between capacitance and product quantity.

While the foregoing discussion and FIGS. 1 and 2 are directed to a configuration in which the first and second conductors 14, 16 are positioned proximate the left and right side walls 26, 28, respectively, other parallel and opposed configurations of the first and second conductors 14, 16 may be used to configure the capacitor assembly 20 as a parallel plate capacitor. In one alternative configuration, the first conductor 14 may be positioned proximate the front wall 22 (FIG. 3) of the container 12 and the second conductor 16 may be positioned proximate the rear wall 24 (FIG. 3) of the container 12. In another alternative configuration, the first conductor 14 may be positioned proximate the base wall 30 (FIG. 3) of the container 12 and the second conductor 16 may be positioned proximate the upper wall 32 (FIG. 3) of the container 12.

At this point, those skilled in the art will appreciate that the capacitor assembly 20 may be configured other than as a parallel plate capacitor. Referring to FIG. 6, in one alternative embodiment, the first and second conductors 14, 16 may be arranged on the same side wall 26′ of the container 12′ in a spaced apart (one above the other), but co-planar configuration. Without being limited to any particular theory, a co-planar arrangement of the first and second conductors 14, 16 may be effective when the container 12′ houses two or more laterally adjacent rows of products 38, as shown in FIG. 6.

The disclosed system for measuring product quantity in a container may be associated with a product dispensing system. Various product dispensing systems may be constructed (or modified) to include the disclosed system for measuring product quantity in a container.

Referring to FIG. 7, one embodiment of the disclosed product dispensing system, generally designated 100, may include a container 102 and a dispenser 104. The container 102 may be mounted on the dispenser 104 such that products initially housed in the container 102 may move to, and may be dispensed from, the dispenser 104.

As shown in FIG. 8, the container 102 may be generally configured in a manner similar to the container 12 shown in FIG. 3. The container 102 may include a container opening 106 through which products 108 (FIG. 7) may pass as the products 108 move from the container 102 to the dispenser 104.

In a first expression of the product dispensing system 100, the conductors 14, 16 of the disclosed system 10 (FIGS. 1 and 2) for measuring product quantity may be incorporated into the opposed side walls 110, 112 of the container 102. Therefore, the container 102 may be pre-formed as the capacitor assembly 20 (FIG. 1) of the system 10 for measuring product quantity in a container.

Referring to FIG. 9, in one particular construction of the first expression, the side walls 110, 112 (only side wall 110 is shown in FIG. 9) of the container 102 may be formed as a layered structure 120 that includes a substrate layer 122, a conductor layer 14 and a top layer 124. The substrate layer 122 may be paperboard or the like, and may provide structural integrity to the layered structure 120. The conductor layer 14 may be the conductor of the system 10 (FIGS. 1 and 2) for measuring product quantity. For example, the conductor layer 14 may be a layer of metal foil, such as aluminum foil. The top layer 124 may secure the conductor layer 14 to the substrate layer 122. For example, the top layer 124 may be a layer of polymeric material, such as polyethylene, used to laminate the conductor layer 14 to the substrate layer 122.

Thus, in accordance with the first expression, capacitance (and hence product quantity) may be determined by coupling the capacitance meter 18 (FIG. 8) to the side walls 110, 112 of the container 102.

In a second expression of the disclosed product dispensing system 100 (FIG. 7), the conductors 14, 16 of the disclosed system 10 (FIGS. 1 and 2) for measuring product quantity may be incorporated into the dispenser 104.

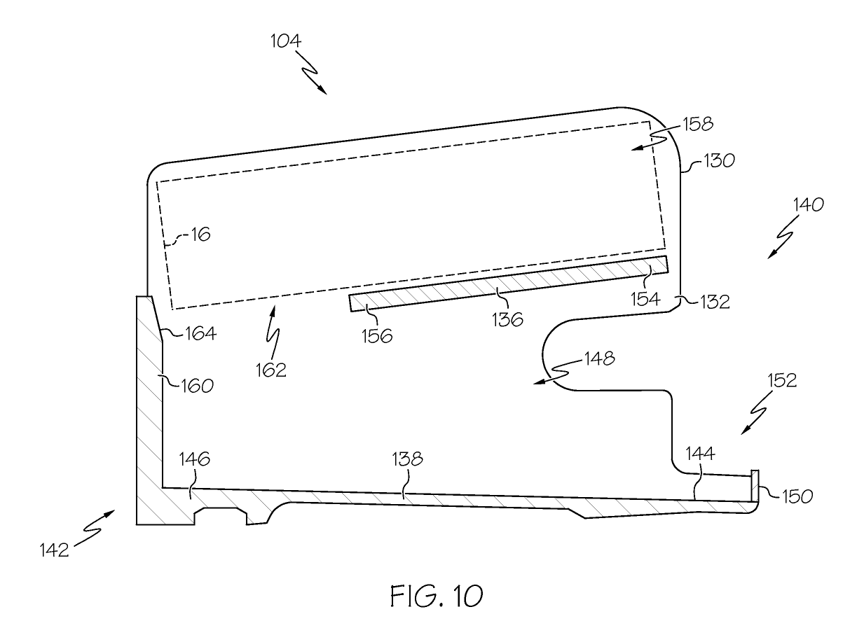

Referring to FIGS. 7 and 10, the dispenser 104 may include a dispenser frame 130 that supports the container 102 in a desired configuration, such as a slightly declined, but generally horizontal configuration, as shown in FIG. 7. The container 102 may be positioned on the frame 130 of the dispenser 1104 to allow products 108 to dispense from the container 102 (by way of the container opening 106 shown in FIG. 8) to the dispenser 104.

The frame 130 may include a first (e.g., right) side wall 132, a second (e.g., left) side wall 134 (FIG. 7), an upper support deck 136 and a lower support deck 138. The right side wall 132 may be laterally spaced from the left side wall 134, and may be generally parallel with the left side wall 134. The frame 130 may include a first (front) end 140 and a second (rear) end 142 longitudinally opposed from the front end 140.

The lower support deck 138 may laterally extend between the right and left side walls 132, 134, and may include a front end 144 that longitudinally extends toward the front end 140 of the frame 130 and a rear end 146 that longitudinally extends toward the rear end 142 of the frame 130. Therefore, the lower support deck 138 and the side walls 132, 134 may define a lower level 148 of the frame 130.

The lower support deck 138 may be inclined from the front end 144 to the rear end 146 (i.e., the rear end 146 may be elevated relative to the front end 144) such that products 108 (FIG. 7) deposited proximate the rear end 146 of the lower support deck 138 roll down to the front end 144 of the lower support deck 138 under the force of gravity.

A stop 150 may be positioned proximate the front end 144 of the lower support deck 138 to prevent products 108 from rolling beyond the front end 144 of the lower support deck 138. For example, the stop 150 may be connected to (e.g., integral with) the lower support deck 138, and may form an abrupt stop or an upward curve at the front end 144 of the lower support deck 138. Therefore, as shown in FIG. 7, the stop 150 may collect products 108 at the front end 144 of the lower support deck 138, thereby defining a product display area 152 at the front end 144 of the lower support deck 138.

The upper support deck 136 may laterally extend between the right and left side walls 132, 134, and may include a front end 154 that longitudinally extends toward the front end 140 of the frame 130 and a rear end 156 that longitudinally extends toward, but not to, the rear end 142 of the frame 130. Therefore, the upper support deck 136 and the side walls 132, 134 may define an upper level 158 of the frame 130.

The spacing between the rear end 156 of the upper support deck 136 and the rear end 142 of the frame 130 (e.g., rear wall 160 of the frame 130) may define a dispenser opening 162. The dispenser opening 162 may function as a chute to allow products 16 to drop (under the force of gravity) from the upper level 158, through the dispenser opening 162, and down to the lower level 148 of the frame 130.

The upper support deck 136 may be declined from the front end 154 to the rear end 156 (i.e., the front end 154 may be elevated relative to the rear end 156). Therefore, under the force of gravity, products 108 supported on the upper support deck 136 may roll down to the rear end 156 of the upper support deck 136, may pass through the dispenser opening 162 down to the lower level 148 of the frame 130 and, ultimately, may move to the product display area 152.

A rear wall 160 may be positioned at the rear end 142 of the frame 130 between the right and left side walls 132, 134. The rear wall 160 may serve as (or may include) a rear stop 164 that inhibits rearward horizontal movement of the container 102 (FIG. 7) along the upper support deck 136 beyond the rear wall 160.

Prior to dispensing products by way of the dispenser 104, the container opening 106 (FIG. 8) may be formed in the container 102. The container opening 106 may be pre-formed in the container 102 and, therefore, no opening step may be required. If the container 102 includes a tear-away access panel, then the access panel may be separated (at least partially) from the container 102 to form the container opening 106.

While the container opening 106 may be manually formed prior to loading the container 102 onto the upper support deck 136 of the dispenser 104, an optional opening tool may be associated with the dispenser 104 to effect automatic formation of the container opening 106 upon loading the container 102 onto the upper support deck 136 of the dispenser 104. One product dispensing system having an opening tool is disclosed in greater detail in U.S. Pat. No. 7,922,437 to Loftin et al., which issued on Apr. 12, 2011, the entire contents of which are incorporated herein by reference. Another product dispensing system having an opening tool is disclosed in greater detail in U.S. patent application Ser. No. 13/032,734 filed on Feb. 23, 2011 by Gelardi et al., the entire contents of which are incorporated herein by reference.

In one particular implementation of the second expression of the disclosed product dispensing system 100, the conductors 14, 16 of the disclosed system 10 (FIGS. 1 and 2) for measuring product quantity may be incorporated into the side walls 132, 134 (in the upper level 158) of the frame 130 of the dispenser 104. Therefore, the conductors 14, 16 and the container 102 may effectively form a capacitor assembly 20 (FIG. 1) when the container 102 is loaded onto the upper support deck 136 of the dispenser 104.

Thus, in accordance with the second expression, capacitance (and hence product quantity) may be determined by coupling the capacitance meter 18 (FIG. 1) to the dispenser 104 of the product dispensing system 100.

In yet another embodiment, the disclosed system for measuring product quantity in a container may be associated with a hand-held device.

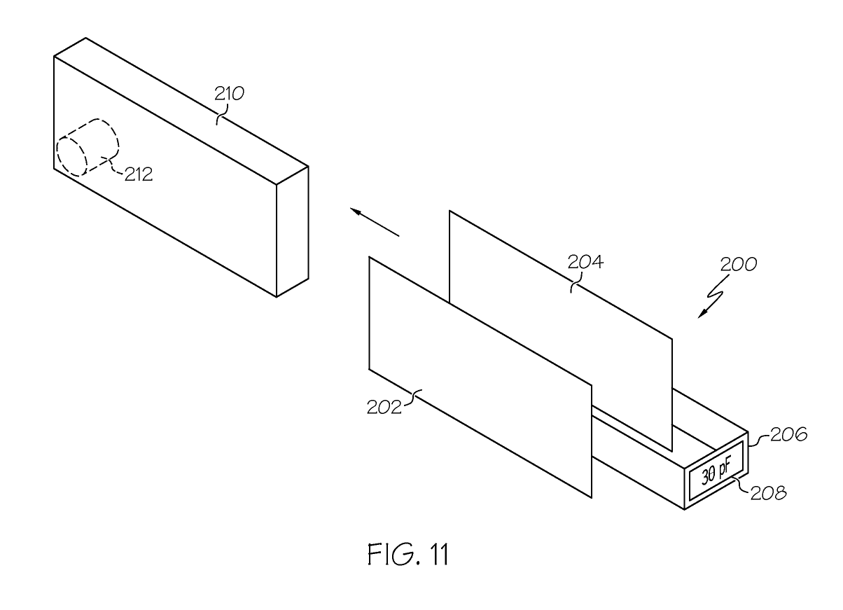

Referring to FIG. 11, a hand-held device 200 may include a first conductor 202, a second conductor 204, a handle 206 and a capacitance meter 208. The first and second conductors 202, 204 may be arranged in parallel and may be spaced apart a distance, which may be dictated by the lateral width of the container 210 to be measured by the hand-held device 200. The handle 206 may physically connect the first and second conductors 202, 204. Optionally, the capacitance meter 208 may be mounted on (or otherwise associated with) the handle 206.

Thus, the number of products 212 housed in the container 210 may be measured by placing the hand-held device 200 relative to the container 210 such that the container 210 is positioned between the first and second conductors 202, 204, thereby effectively forming a temporary capacitor assembly. With the hand-held device 200 properly position, the capacitance of the temporary capacitor assembly may be measured and correlated to a product quantity value using a known relationship for such a system. Once the measurement is taken, the hand-held device 200 may be withdrawn.

Accordingly, the disclosed system and method for measuring product quantity in a container may accurately and consistently measure the number of products housed in a container without the need for opening and inspecting the container.

Although various embodiments of the disclosed system and method for measuring product quantity in a container have been shown and described, modifications may occur to those skilled in the art upon reading the specification. The present application includes such modifications and is limited only by the scope of the claims.

What is claimed is:

1. A system for measuring product quantity comprising:
a container that defines an internal volume;
a plurality of products positioned in said internal volume;
a first conductor positioned proximate said container;
a second conductor positioned proximate said container, wherein said container, said plurality of products, said first conductor and said second conductor form an assembly; and
a meter electrically coupled to said first conductor and said second conductor to measure an electrical quantity of said assembly.

2. The system of claim 1 wherein said electrical quantity is capacitance.

3. A system for measuring product quantity comprising:
a container that defines an internal volume;
a plurality of products positioned in said internal volume;
a first conductor positioned proximate said container;
a second conductor positioned proximate said container; and
a capacitance meter electrically coupled to said first conductor and said second conductor.

4. The system of claim 3 wherein said container comprises paperboard.

5. The system of claim 3 wherein said container comprises:
a front wall opposed from a rear wall;
a base wall opposed from an upper wall; and
a first side wall opposed from a second side wall.

6. The system of claim 5 wherein said first conductor is positioned proximate said first side wall and said second conductor is positioned proximate said second side wall.

7. The system of claim 6 wherein said first conductor has a major surface having a first surface area and wherein said first side wall has a second surface area, and wherein said first surface area is at least 75 percent of said second surface area, and wherein said second conductor has a major surface having a third surface area and wherein said second side wall has a fourth surface area, and wherein said third surface area is at least 75 percent of said fourth surface area.

8. The system of claim 5 wherein said first conductor is incorporated into said first side wall and said second conductor is incorporated into said second side wall.

9. The system of claim 3 wherein each product of said plurality of products is configured to roll about a rolling axis.

10. The system of claim 3 wherein said container defines a container opening into said internal volume, and wherein said container opening is sized to allow at least one product of said plurality of products to pass therethrough.

11. The system of claim 3 wherein said first and said second conductors are substantially flat.

12. The system of claim 3 wherein said first and said second conductors are laminated onto said container.

13. The system of claim 3 wherein said first conductor is coincident with a first plane and said second conductor is coincident with a second plane, said second plane being substantially parallel with said first plane.

14. The system of claim 13 wherein said first plane is spaced a distance from said second plane, and wherein said container is positioned between said first conductor and said second conductor.

15. A product dispensing system comprising said system of claim 3.

16. The product dispensing system of claim 15 comprising:
a dispenser frame having a front end and rear end, said dispenser frame comprising:
an upper support deck extending between said front end and said rear end; and
a lower support deck positioned below said upper support deck, said lower support deck defining a product display area,
wherein said container is positioned on said upper support deck.

17. The product dispensing system of claim 16 wherein said first conductor and said second conductor are connected to said dispenser frame.

18. The product dispensing system of claim 16 wherein said first conductor and said second conductor are connected to said container.

19. A hand-held device comprising said system of claim 3.

20. A method for determining a number of products in a container, said method comprising the steps of:
positioning said container between a first conductor and a second conductor to form an assembly;
measuring an electrical quantity of said assembly; and
correlating said measured electrical quantity to said number of products in said container.
